(19) United States
(12) Patent Application Publication
(10) Pub. No.: US 2008/0210930 A1
(43) Pub. Date: Sep. 4, 2008

(54) Metal Complex, Light-Emitting Device, and Image Display Apparatus

(75) Inventors: Jun Kamatani, Tokyo (JP); Shinjiro Okada, Kanagawa-ken (JP); Takao Takiquchi, Tokyo (JP); Minako Nakasu, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/720,416

(22) PCT Filed: Nov. 29, 2005
(86) PCT No.: PCT/JP05/22256

§ 371 Date: May 29, 2007

(30) Foreign Application Priority Data
Nov. 30, 2004 (JP) 2004/346257

(51) Int. Cl. H01L 51/00; C09K 11/06

(52) U.S. Cl. 257/40; 252/301.16; 257/E51.001

(57) ABSTRACT

To provide a novel metal complex suitable as a compound for an organic EL device. A metal complex including a partial structure represented by the following general formula (1): in which R in the general formula (1) has a partial structure represented by the following general formula (2) or (3).

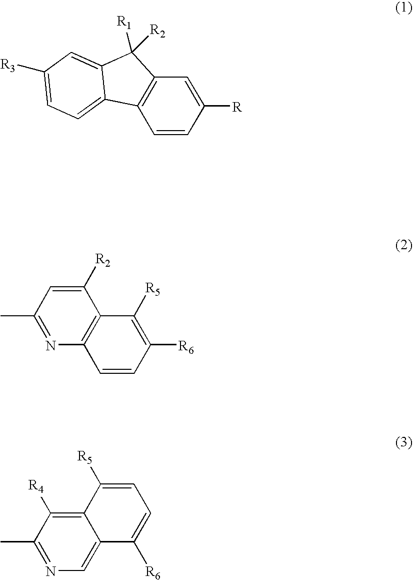

### TECHNICAL FIELD

The present invention relates to a novel metal complex for a light-emitting device and an organic light-emitting device (also referred to as an organic electroluminescence device or an organic EL device) for use in a flat light source, a flat display, or the like.

### BACKGROUND ART

In an old example of an organic light-emitting device, a voltage has been applied to an anthracene deposited film to emit light (Thin Solid Films, 94, (1982), 171). In recent years, however, active research has been vigorously conducted on the transformation of an organic light-emitting device as a light-emitting device having high-speed response and high efficiency into a device including the development of a material for the device. This is because the area of the organic light-emitting device can be increased more easily than that of an inorganic light-emitting device, the device provides desired color development through the development of various new materials, and the device has advantages including its ability to be driven at a low voltage.

For example, as detailed in Macromol. Symp. 125, 1 to 48 (1997), an organic EL device generally includes: a transparent substrate; two (upper and lower) electrodes formed on the transparent substrate; and an organic layer including a light emission layer, the organic layer being interposed between the electrodes.

In recent years, investigation has been made into a device using not only conventional light emission utilizing fluorescence upon transition from a singlet exciton to a ground state but also phosphorescence via a triplet exciton described in each of Improved energy transfer in electrophosphorescent device (D. F. O'Brien et al., Applied Physics Letters Vol 74, No 3, p 422 (1999)) and Very high-efficiency green organic light-emitting devices based on electrophosphorescence (M. A. Baldo et al., Applied Physics Letters Vol 75, No 1, p 4 (1999)). In each of those documents, an organic layer having a four-layer structure has been mainly used. The organic layer is composed of a hole transport layer, a light emission layer, an exciton diffusion-prevention layer, and an electron transport layer, from an anode side. Materials used are a carrier-transporting material and a phosphorescent material Ir(ppy)₃ shown below.

A variety of light beams ranging from an ultraviolet light beam to an infrared light beam can be emitted by changing the kind of a fluorescent organic compound. In recent years, active research has been conducted on various compounds.

In addition to an organic light-emitting device using any one of such low-molecular-weight materials as described above, an organic light-emitting device using a conjugate polymer has been reported by the group of the University of Cambridge (Nature, 347, 539 (1990)). The report has observed light emission from a single layer by forming polyphenylenevinylene (PPV) into a film by means of a coating system.

As described above, an organic light-emitting device has recently shown significant progress. The organic light-emitting device is characterized in that it can be transformed into a high-speed response, thin, and lightweight light-emitting device which can be driven at a low applied voltage and has high luminance and a variety of emission wavelengths. The characteristic suggests the potential of the device to find use in a wide variety of applications.

However, at present, output of light having additionally high luminance, or additionally high conversion efficiency has been requested. In addition, there still remain a large number of problems in terms of durability such as a change with time due to long-term use and deterioration due to an atmospheric gas containing oxygen or due to moisture. Furthermore, red light must be emitted at good color purity when the application of the device to a full-color display or the like is taken into consideration. However, those problems have not been sufficiently solved yet.

### DISCLOSURE OF THE INVENTION

An object of the present invention is to provide a novel metal complex suitable as a compound for an organic EL device.

Another object of the present invention is to provide an organic light-emitting device using the metal complex of the present invention, the organic light-emitting device being capable of outputting light having high luminance at high efficiency. Another object of the present invention is to provide a highly durable organic light-emitting device. Another object of the present invention is to provide an organic light-emitting device that can be produced easily and at a relatively low cost.

That is, according to one aspect of the present invention, there is provided a metal complex including a partial structure represented by the following general formula (1):

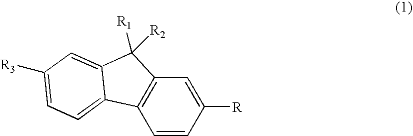

in which R in the general formula (1) has a partial structure represented by the following general formula (2) or (3):

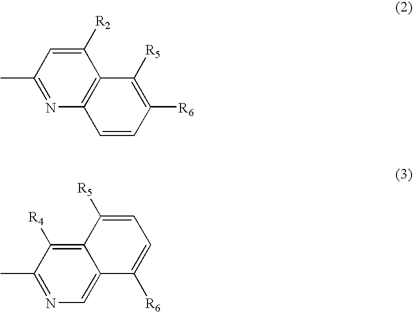

(R₁ to R₆ are each independently selected from a hydrogen atom, a halogen atom, a straight or branched alkyl group having 1 to 20 carbon atoms (one methylene group of the alkyl group, or two or more methylene groups thereof not adjacent to each other may be substituted by —O—, —S—, —CO—, —CO—O—, —O—CO—, —CH═CH—, or —C≡C—, one or two or more methylene groups may be substituted by an arylene group which may have a substituent or a divalent heterocyclic group which may have a substituent, and a hydrogen atom in the alkyl group may be substituted by a fluorine atom), an amino group which may have a substituent, a silyl group which may have a substituent, a phenyl group which may have a substituent, a naphthyl group, a pyrenyl group, a phenanthrenyl group, a crysenyl group, a fluoranthenyl group, a triphenylenyl group, and a heterocyclic group which may have a substituent. In addition, adjacent atoms or groups may bind to each other to form a ring structure).

According to another aspect of the present invention, there is provided a light-emitting device including: a pair of electrodes; and at least one layer containing an organic compound, the layer being interposed between the electrodes, in which the at least one layer containing an organic compound is a layer containing the above-described metal complex.

According to another aspect of the present invention, there is provided an image display apparatus including: the above-described light-emitting device; and means for supplying an electrical signal to the light-emitting device.

The light-emitting device of the present invention using the metal complex of the present invention is an excellent device capable of not only emitting light at high efficiency but also maintaining high luminance for a long time period. The metal complex of the present invention is suitable as a compound for an organic EL device. In addition, the light-emitting device of the present invention can be an excellent display device.

### BRIEF DESCRIPTION OF THE DRAWINGS

FIGS. 1A, 1B, and 1C are views each showing an example of a light-emitting device of the present invention.

FIG. 2 is a view schematically showing an example of the structure of a panel including an EL device and driving means.

FIG. 3 is a view showing an example of a pixel circuit.

FIG. 4 is a schematic view showing an example of the sectional structure of a TFT substrate.

FIG. 5 is a schematic sectional view of a light-emitting device produced in each of Examples.

### BEST MODE FOR CARRYING OUT THE INVENTION

At first, the metal complex of the present invention will be described.

The metal complex of the present invention is a metal complex having a ligand using fluorenyl-2-quinoline or isoquinoline as a basic skeleton. Providing a metal complex, especially a complex using Ir as a center metal with a ligand using fluorenyl-2-quinoline or isoquinoline as a basic skeleton minimizes the number of rotating sites in the light emission ligand, whereby deactivation upon light emission can be reduced. In particular, a red light emission material having high MLCT property can be obtained when a center metal is Ir. In particular, the metal complex must have one or more ligands each using fluorenyl-2-quinoline or isoquinoline as a basic skeleton. In a molecule, a metal preferably coordinates with an increased number of sites of this kind.

The presence of a site having the skeleton in a polymer can also result in the formation of a light emission layer.

The metal complex of the present invention is a highly efficient phosphorescent material capable of emitting light suitable for red light emission.

The metal complex of the present invention is preferably one represented by the following general formula (4).

MLₘL′ₙ (4)

(In the formula, L and L′ represent bidentate ligands different from each other. m represents 1, 2, or 3 and n represents 0, 1, or 2; provided that m+n=3. A partial structure MLₘ is represented by the following general formula (5) or (6), and a partial structure ML′ₙ is represented by the following general formula (7), (8), or (9).

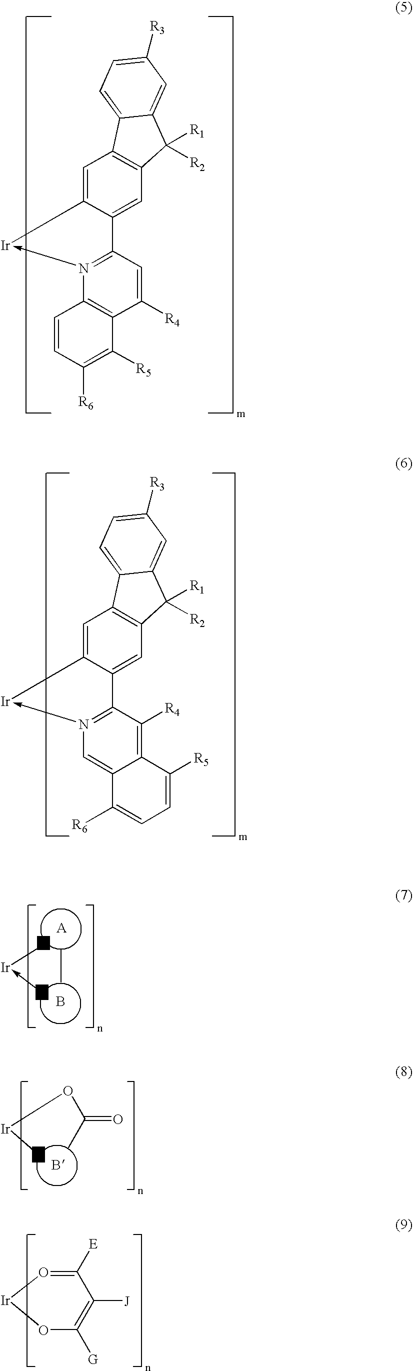

N and C represent a nitrogen atom and a carbon atom, respectively, A represents a cyclic group which may have a substituent bound to a metal atom M via a carbon atom, and B and B′ each represent a cyclic group which may have a substituent bound to the metal atom M via a nitrogen atom.

A and B bind to each other through a covalent bond.

E and G each represent a straight or branched alkyl group having 1 to 20 carbon atoms (a hydrogen atom in the alkyl group may be substituted by a fluorine atom) or an aromatic ring group which may have a substituent {the substituent represents a halogen atom, a cyano group, a nitro group, a trialkylsilyl group (the alkyl groups each independently represent a straight or branched alkyl group having 1 to 8 carbon atoms), or a straight or branched alkyl group having 1 to 20 carbon atoms (one methylene group in the alkyl group, or two or more methylene groups therein not adjacent to each other may be substituted by —O—, —S—, —CO—, —CO—O—, —O—CO—, —CH═CH—, or —C≡C— and a hydrogen atom in the alkyl group may be substituted by a fluorine atom)}.

J's each represent hydrogen, a halogen, a straight or branched alkyl group having 1 to 20 carbon atoms (a hydrogen atom in the alkyl group may be substituted by a fluorine atom), or an aromatic ring group which may have a substituent {the substituent represents a halogen atom, a cyano group, a nitro group, a trialkylsilyl group (the alkyl groups each independently represent a straight or branched alkyl group having 1 to 8 carbon atoms), or a straight or branched alkyl group having 1 to 20 carbon atoms (one methylene group in the alkyl group, or two or more methylene groups therein not adjacent to each other may be substituted by —O—, —S—, —CO—, —CO—O—, —O—CO—, —CH═CH—, or —C≡C— and a hydrogen atom in the alkyl group may be substituted by a fluorine atom)}).

Specific structural formulae of metal complexes are shown below. However, these formulae are intended merely for showing representative examples, and the present invention is not limited thereto.

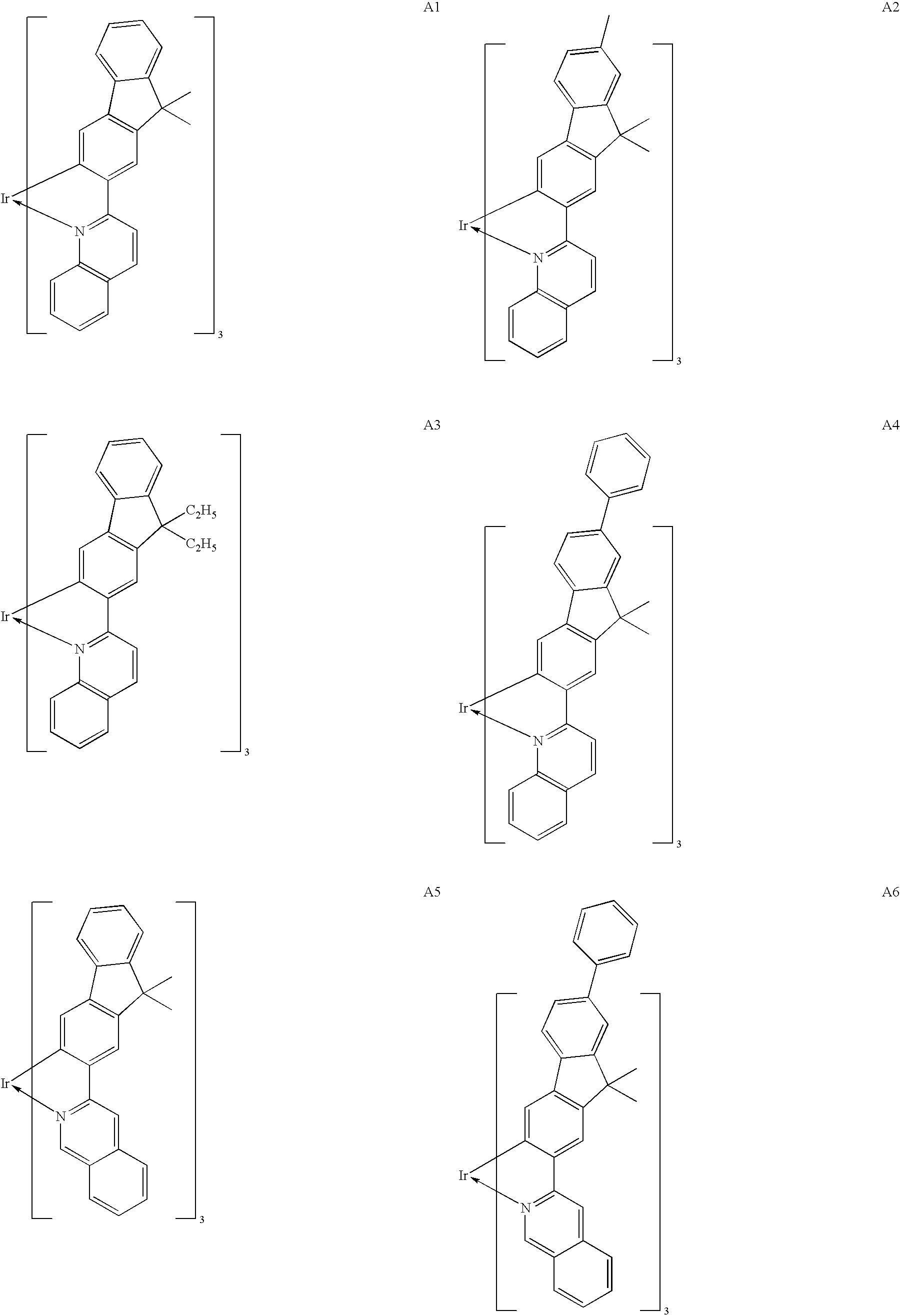

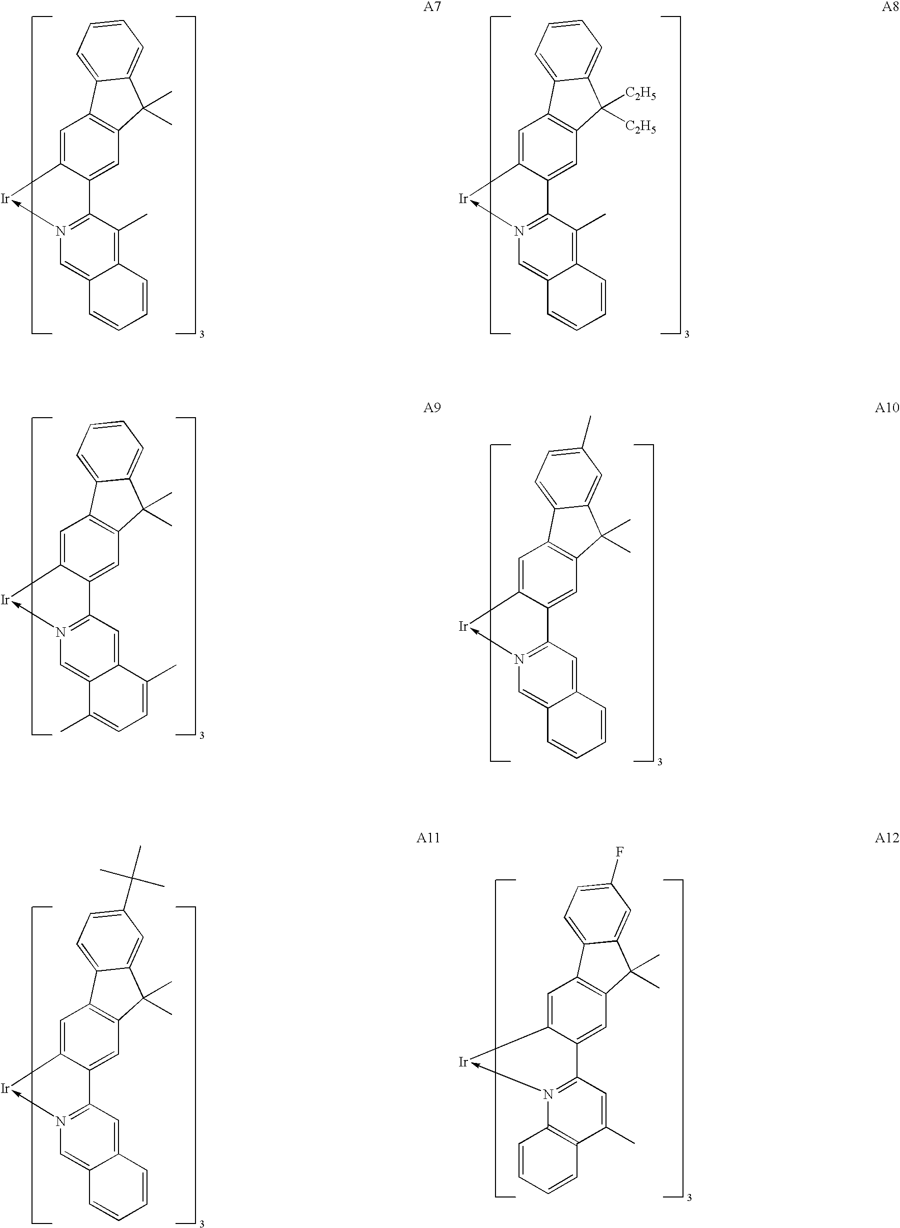

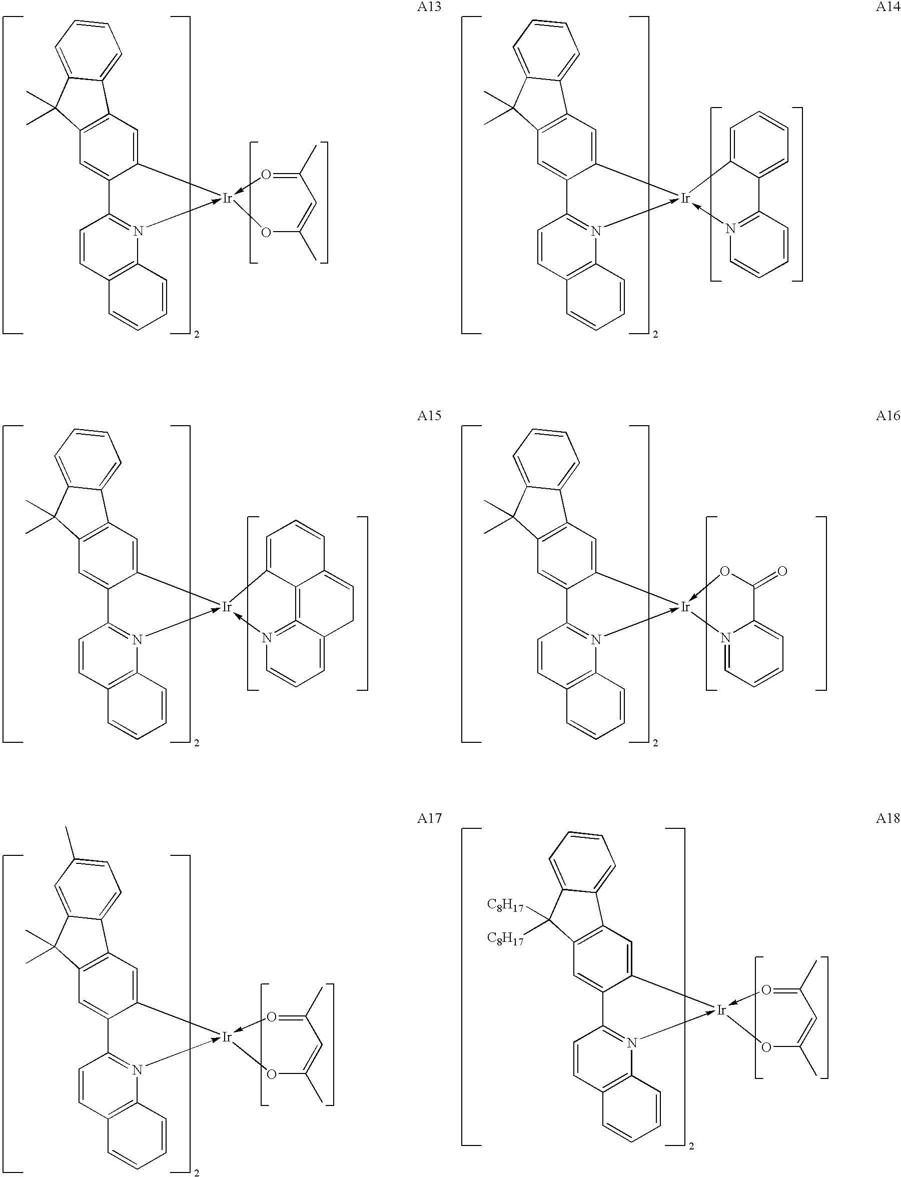

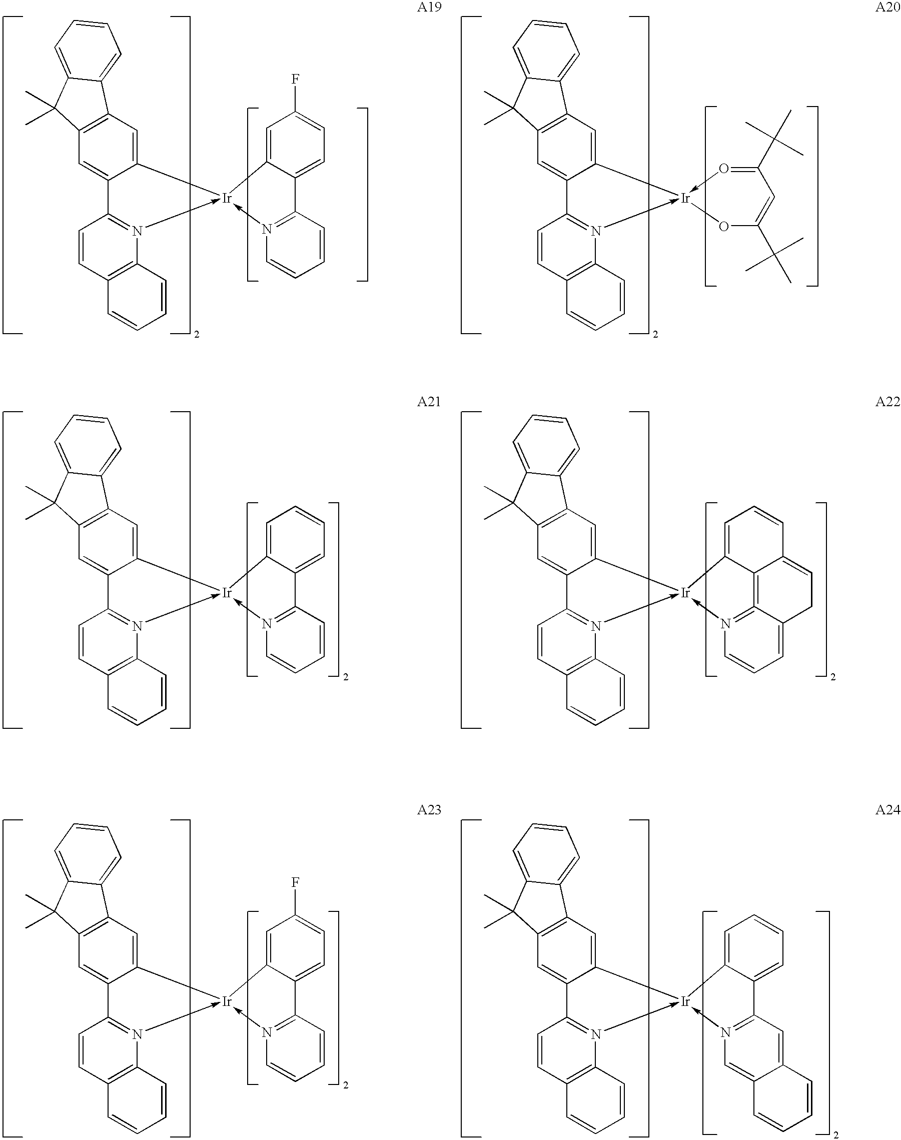

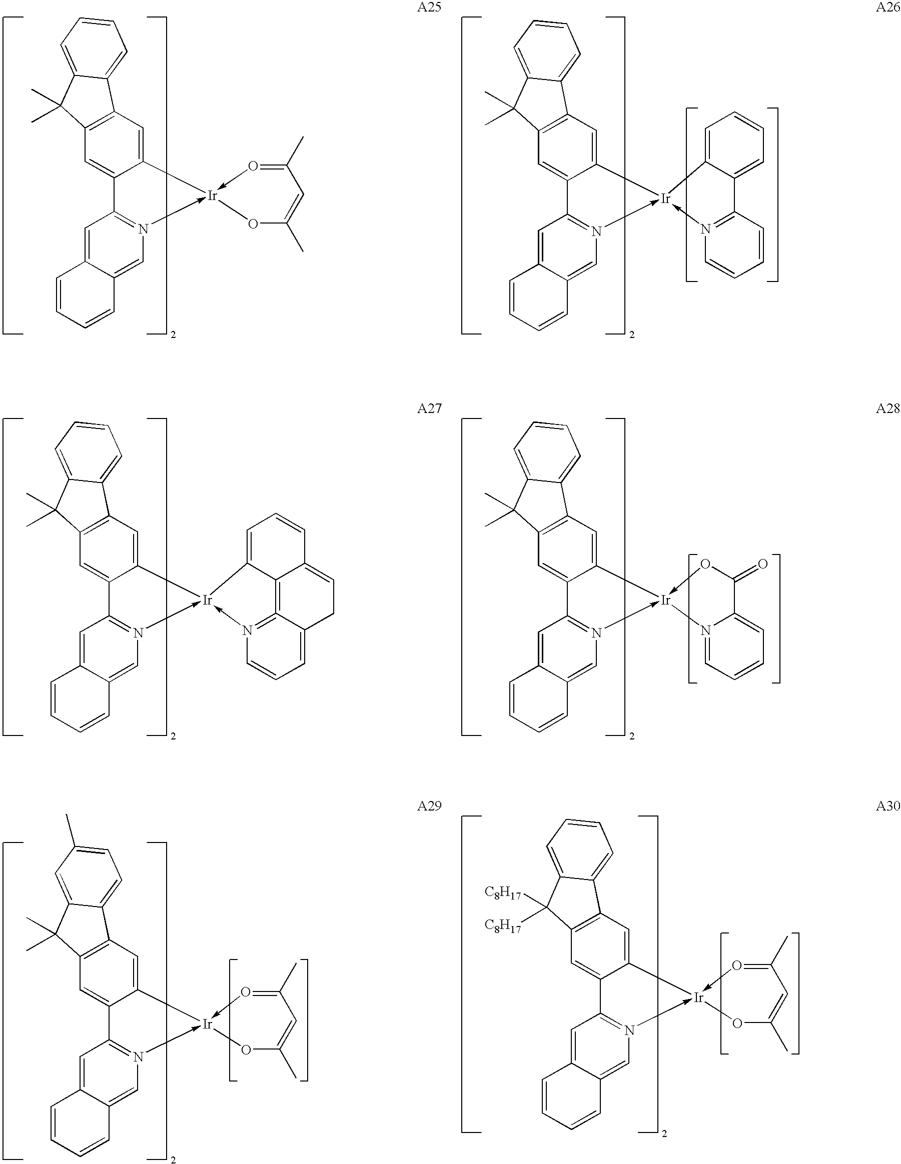

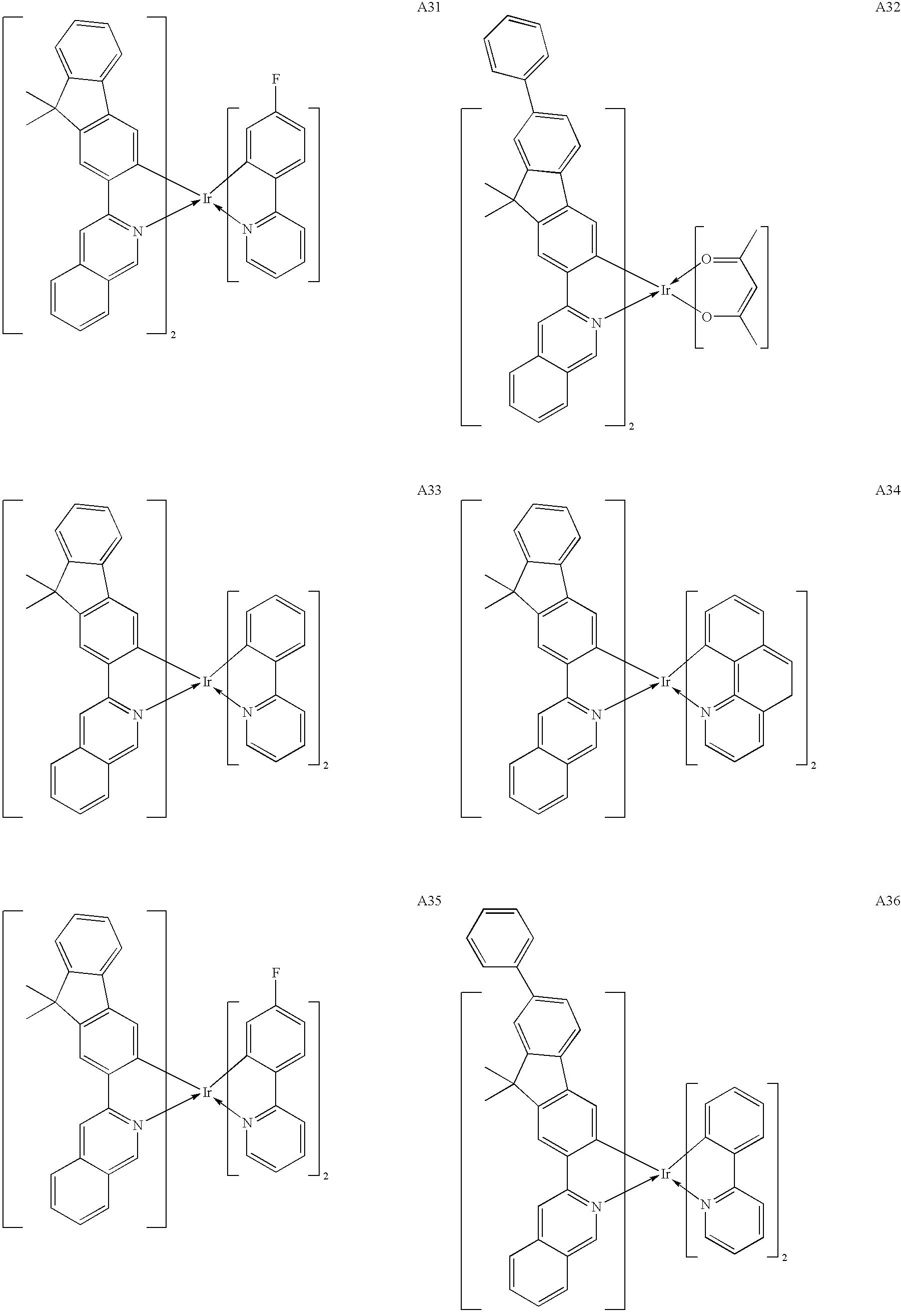

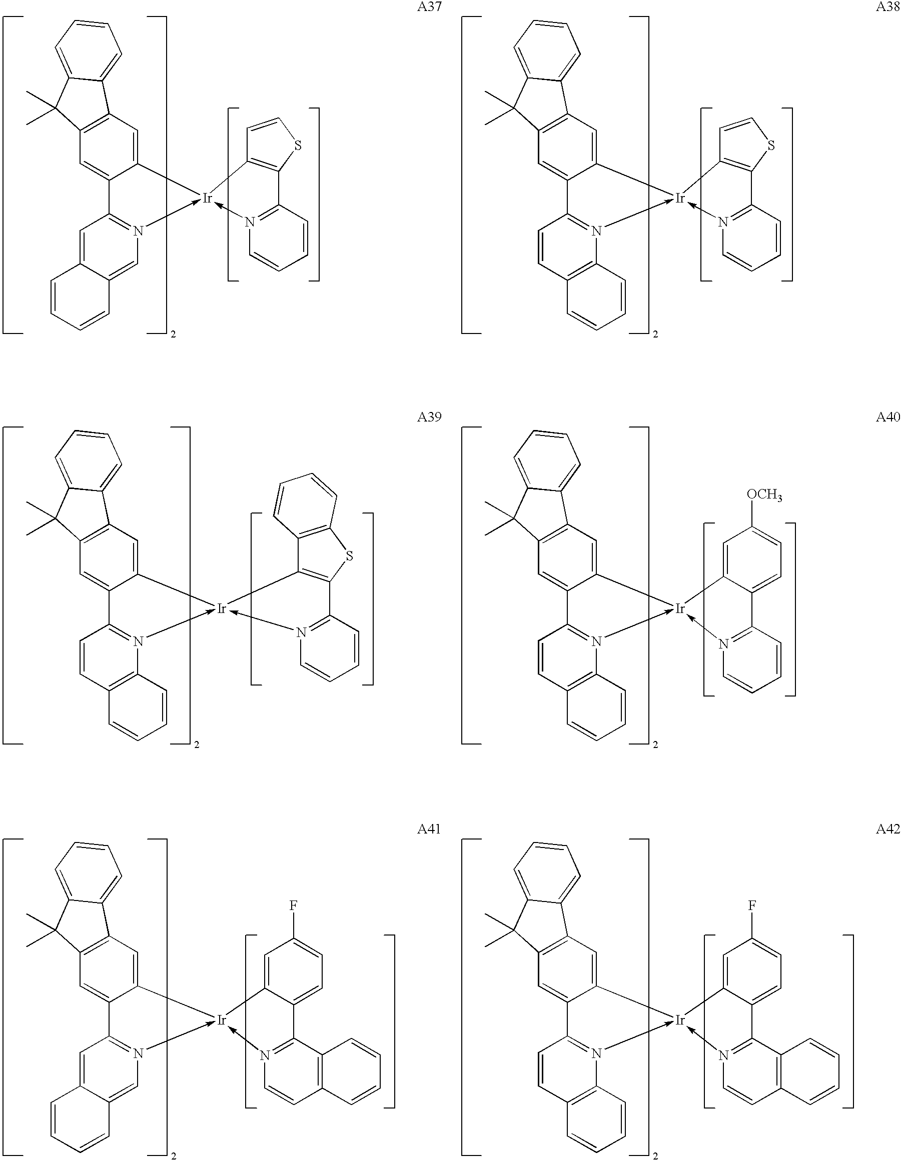

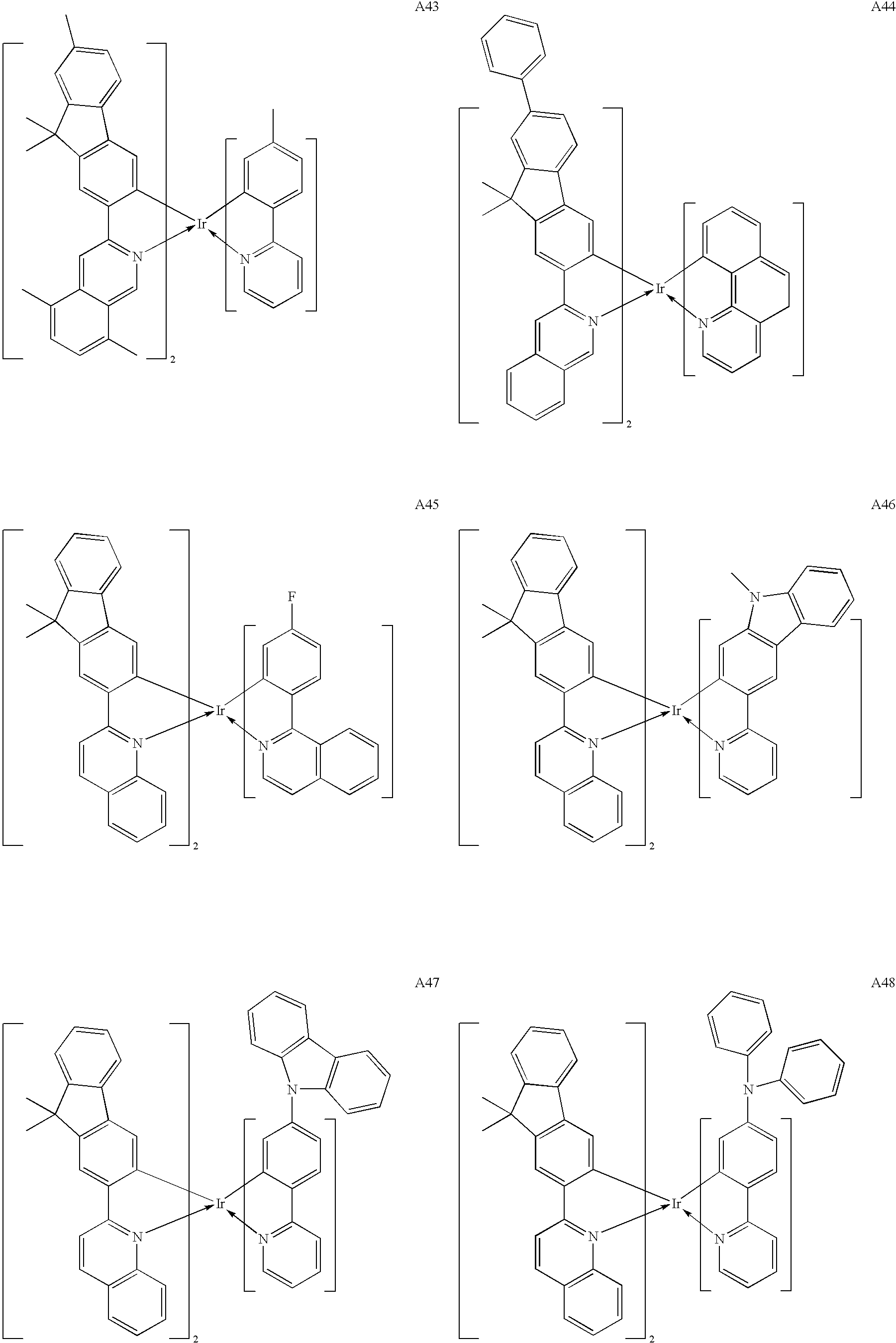

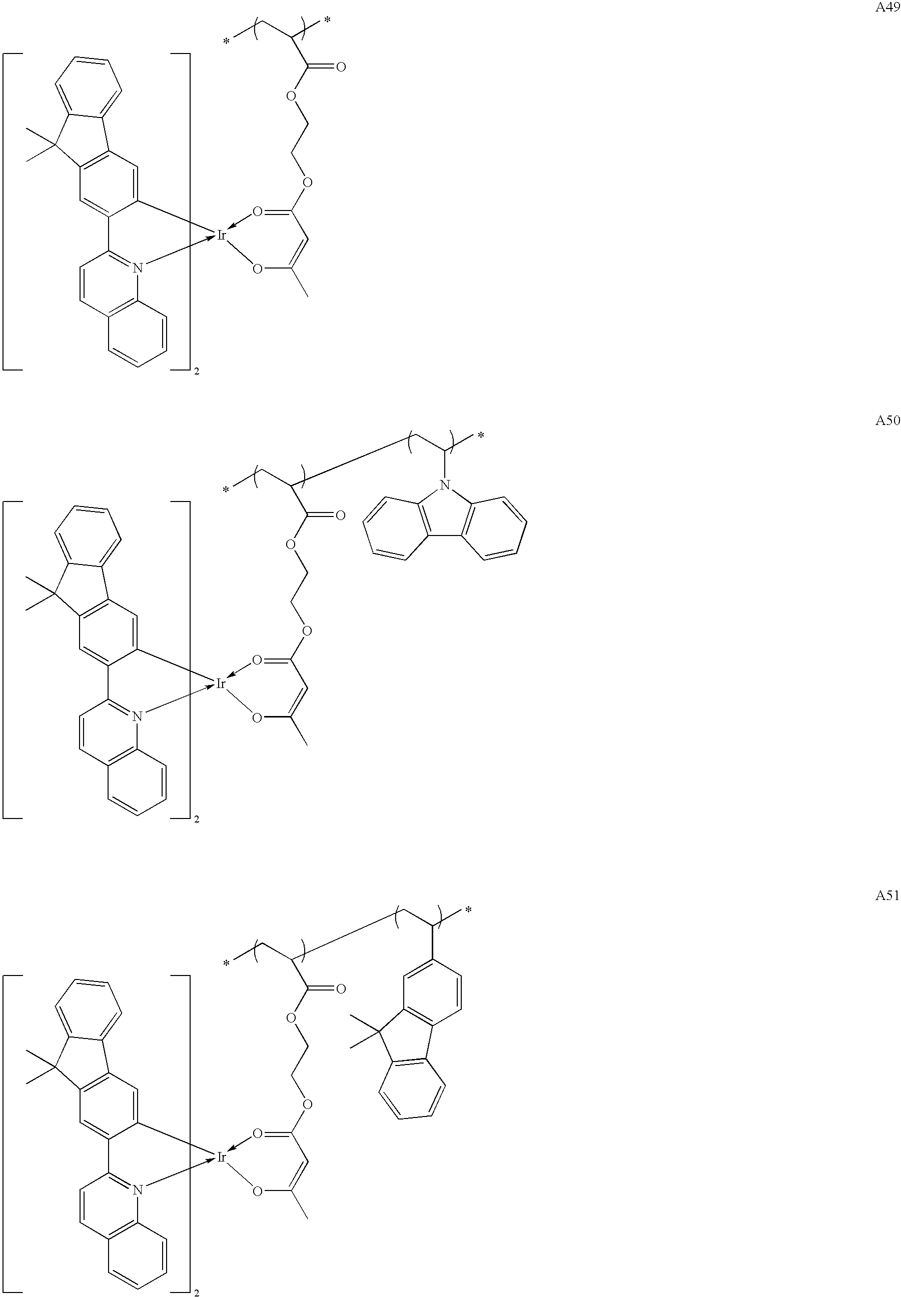

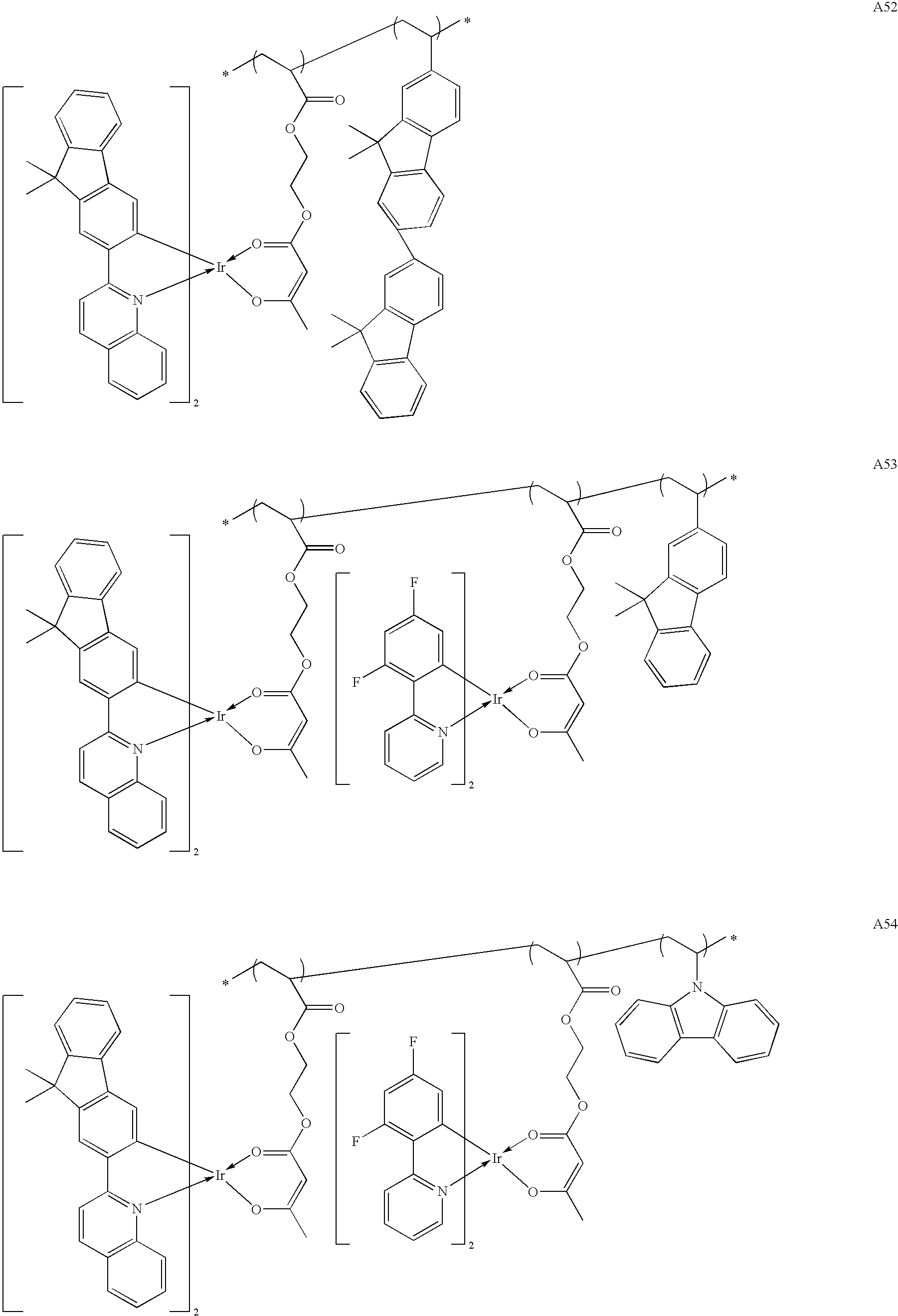

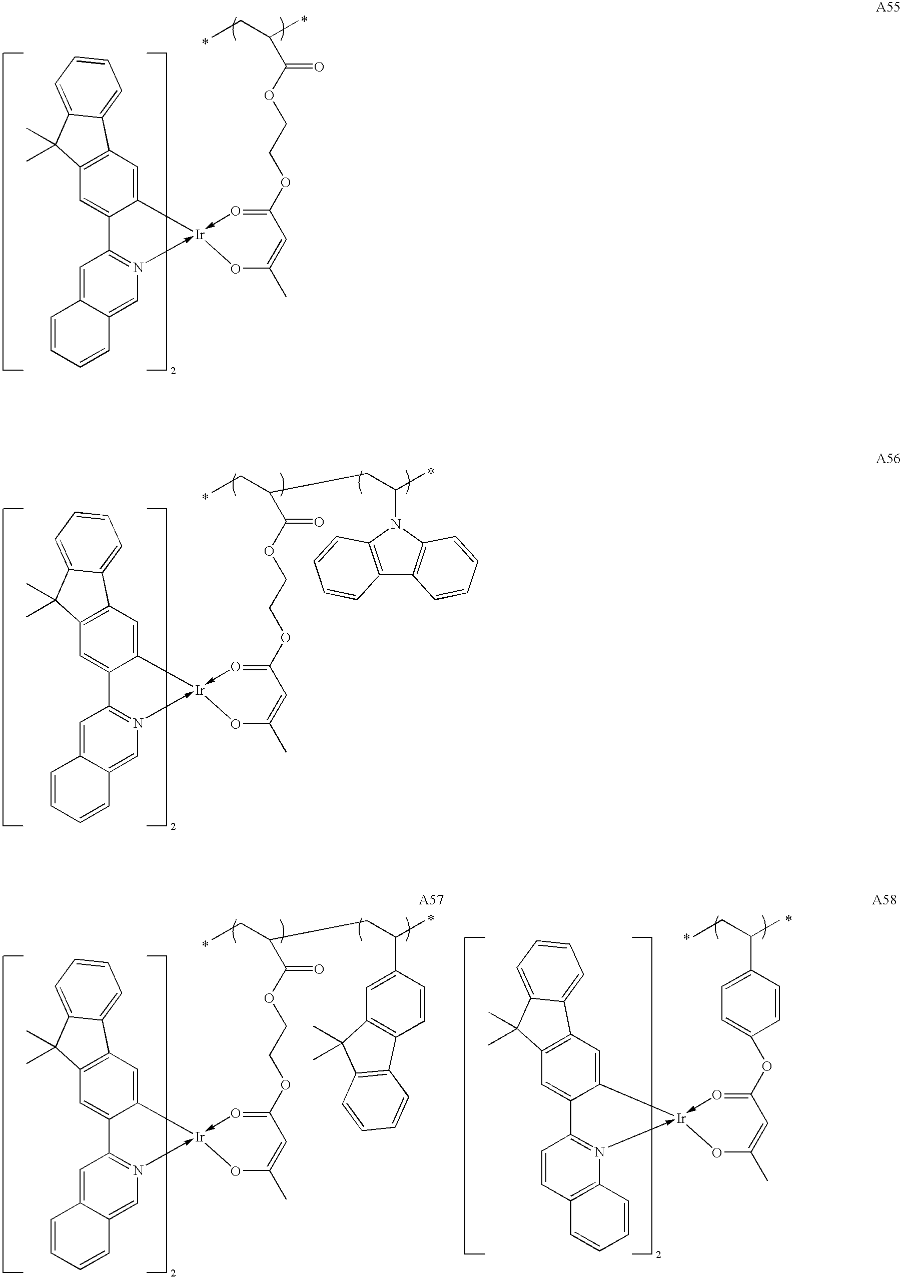

Next, the light-emitting device of the present invention will be described.

The light-emitting device of the present invention using the metal complex of the present invention, especially the light-emitting device using the metal complex as a light emission material of a light emission layer can output light having high luminance at high efficiency, has high durability, and can be produced easily and at a relatively low cost. The light emission layer of the light-emitting device of the present invention may contain multiple phosphorescent materials.

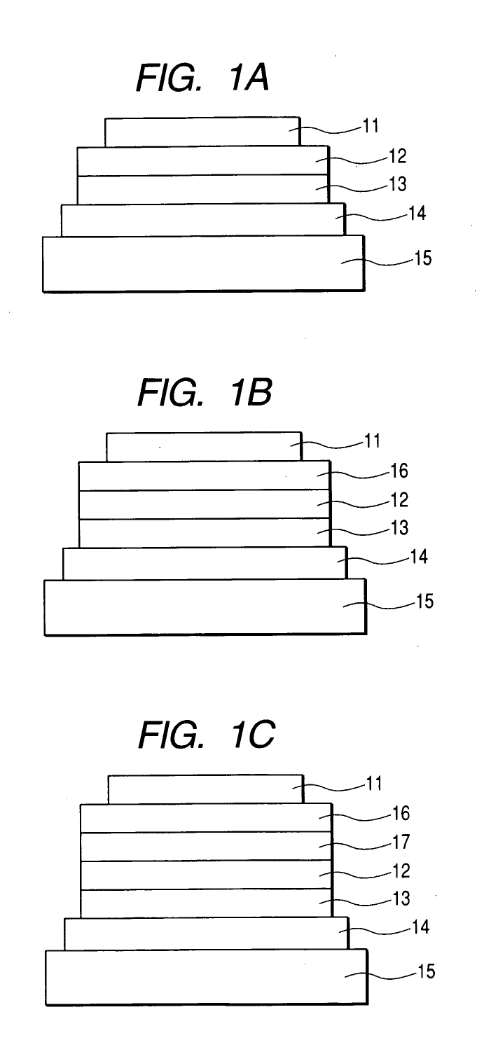

FIGS. 1A to 1C each show the basic device structure of the light-emitting device of the present invention.

As shown in each of FIGS. 1A to 1C, an organic EL device generally includes: a transparent substrate 15; a transparent electrode 14 having a thickness of 50 to 200 nm, the transparent electrode 14 being arranged on the transparent substrate; multiple organic film layers; and a metal electrode 11. The multiple organic film layers are interposed between the transparent electrode 14 and the metal electrode 11.

FIG. 1A shows an example in which the organic layers consist of a light emission layer 12 and a hole transport layer 13. ITO having a large work function or the like is used for the transparent electrode 14 to facilitate the injection of a hole from the transparent electrode 14 to the hole transport layer 13. A metal material having a small work function such as aluminum, magnesium, or an alloy using at least one of them is used for the metal electrode 11 to facilitate the injection of electrons to the organic layers.

The compound of the present invention is preferably used for the light emission layer 12. A material having electron-donating property such as a triphenyl diamine derivative (typified by α-NPD shown below) can also be appropriately used for the hole transport layer 13.

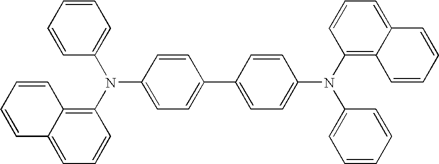

The device having the above structure shows electrical rectifying property. When an electric field is applied in such a manner that the metal electrode 11 serves as a cathode and the transparent electrode 14 serves as an anode, an electron is injected from the metal electrode 11 to the light emission layer 12 and a hole is injected from the transparent electrode 15 thereto.

The injected hole and electron recombine in the light emission layer 12 to generate an exciton, thereby emitting light. At this time, the hole transport layer 13 serves as an electron-blocking layer, and recombination efficiency at an interface between the light emission layer 12 and the hole transport layer 13 increases, whereby emission efficiency increases.

In FIG. 1B, an electron transport layer 16 is interposed between the metal electrode 11 and the light emission layer 12 shown in FIG. 1A. In this case, emission efficiency is increased by separating a light emitting function and electron- and hole-transporting functions to provide a carrier blocking structure having improved effectiveness. An oxadiazole derivative or the like can be used for the electron transport layer 16.

As shown in FIG. 1C, a four-layer structure composed of the hole transport layer 13, the light emission layer 12, an exciton diffusion-prevention layer 17, the electron transport layer 16, and the metal electrode 11 from the side of the transparent electrode 14 as an anode is also desirable.

The light-emitting device of the present invention can find applications in products requiring energy savings and high luminance. Potential applications of the light-emitting device include: light sources for a display apparatus, a lighting system, and a printer; and a backlight for a liquid crystal display apparatus. A flat panel display that has achieved energy savings, high visibility, and a light weight can be achieved when the device of the present invention is applied to a display apparatus. In the case of a light source for a printer, a laser light source portion of a laser beam printer currently in active use can be replaced with the light-emitting device of the present invention. Devices that can be independently addressed are arranged on an array and desired exposure is carried out on a photosensitive drum, whereby an image is formed. The use of the device of the present invention significantly reduces an apparatus volume. An energy saving effect of the present invention is expected to be exerted on a lighting system or a backlight.

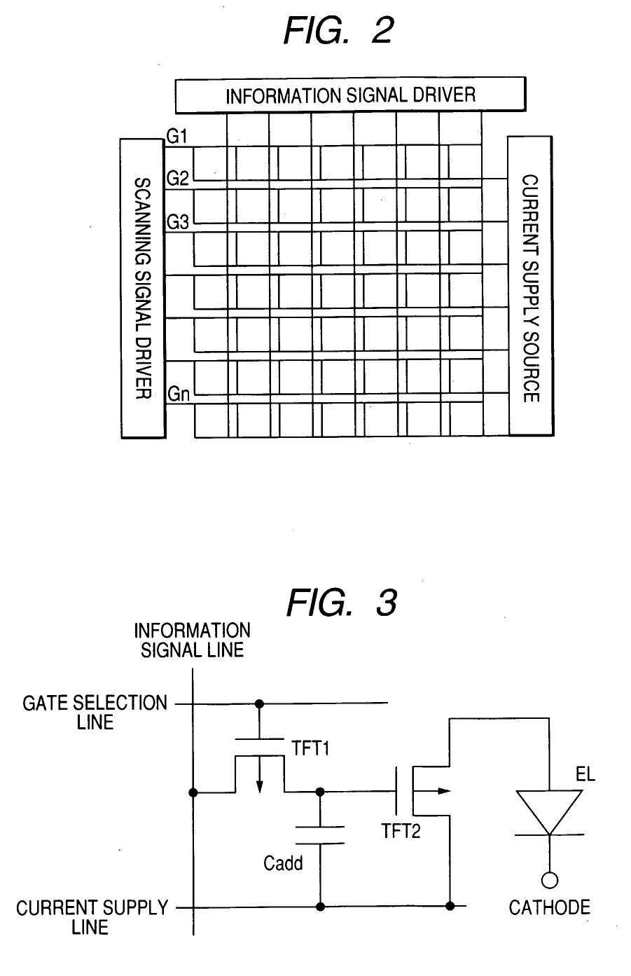

A potential application to a display includes a driving system involving the use of a TFT driver circuit as an active matrix system. Hereinafter, an example in which an active matrix substrate is used in the device of the present invention will be described with reference to FIGS. 2 to 4.

FIG. 2 schematically shows an example of the structure of a panel including an EL device and driving means. A scanning signal driver, an information signal driver, and a current supply source are arranged on the panel, and are connected to a gate selection line, an information signal line, and a current supply line, respectively. A pixel circuit shown in FIG. 3 is arranged at an intersection of the gate selection line and the information signal line. The scanning signal driver sequentially selects the gate selection lines G1, G2, G3, . . . , and Gn. An image signal is applied from the information signal driver in synchronization with the selection.

Next, the operation of the pixel circuit will be described. In the pixel circuit, when a selection signal is applied to a gate selection line, a TFT 1 is turned ON, and then an image signal is supplied to a Cadd to determine the gate potential of a TFT 2. A current is supplied from a current supply line to an EL device in accordance with the gate potential of the TFT 2. The current continues to flow into the EL device until a next scan is performed because the gate potential of the TFT 2 is held in the Cadd until next scan selection is performed on the TFT 1. Thus, light can be emitted at all times during a one-frame period.

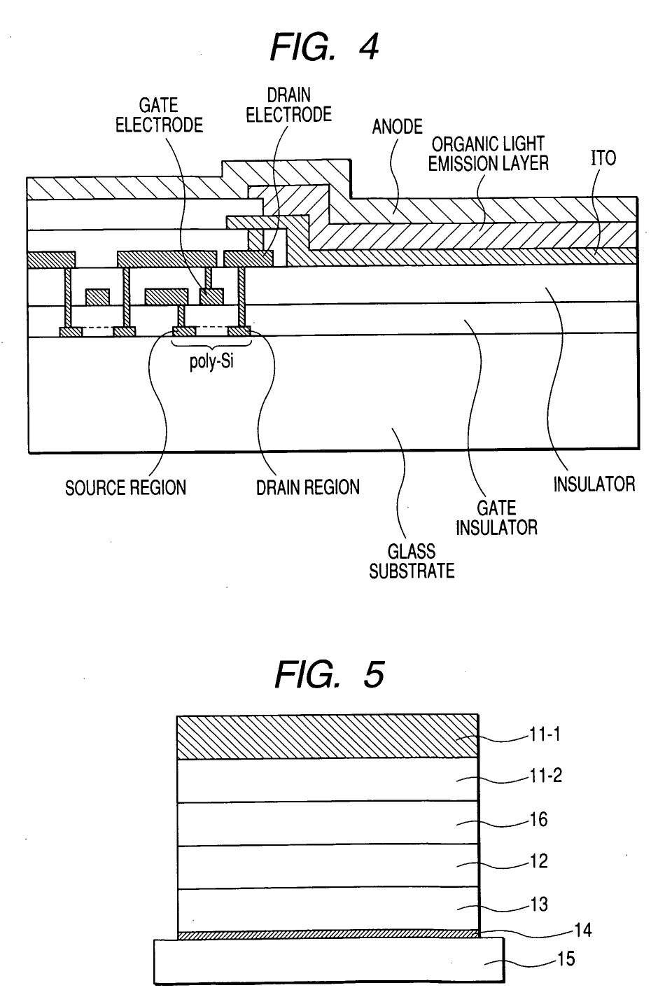

FIG. 4 is a schematic view showing an example of the sectional structure of a TFT substrate to be used in the present invention. A p-Si layer is arranged on a glass substrate, and channel, drain, and source regions are doped with respective necessary impurities. A gate electrode is arranged thereon via a gate insulating layer, and a drain electrode and a source electrode to be connected to the drain region and the source region are formed. An insulating layer and an ITO electrode to serve as a pixel electrode are laminated thereon, and the ITO and the drain electrode are connected to each other through a contact hole.

The present invention is not particularly limited to a switching device, and is easily applicable to a single crystalline silicon substrate, an MIM device, an a-Si type, or the like.

An organic EL display panel can be obtained by sequentially laminating at least one organic EL layer/cathode layer on the ITO electrode. An image with good quality can be displayed stably for a long time period by driving a display panel using the organic compound of the present invention.

Hereinafter, the present invention will be described specifically by way of examples. However, the present invention is not limited to these examples.

At first, representative synthesis examples necessary for synthesizing Exemplified Compounds of the present invention will be shown below.

### EXAMPLE 1

### Synthesis of Exemplified Compound No. A13

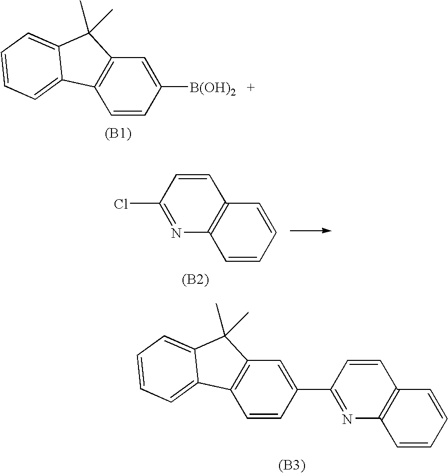

4.7 g (20 mmole) of Compound (B1), 3.3 g (20 mmole) of Compound (B2), 0.22 g (0.17 mmole) of tetrakistriphenylphosphine palladium, 20 ml of a 2M aqueous solution of sodium carbonate, 10 ml of ethanol, and 20 ml of toluene were fed into a 200-ml round-bottomed flask, and the whole was stirred for 6 hours under hot reflux in a stream of nitrogen. The reaction solution was poured into 100 ml of cold water, and 50 ml of toluene were added to the mixture to carry out liquid separation for separating an organic layer, followed by concentration. The resultant solid material was purified by means of a silica gel column (eluent: toluene), and the purified product was recrystallized with hexane to yield 5.3 g of a crystal of Compound (B3) (82% yield).

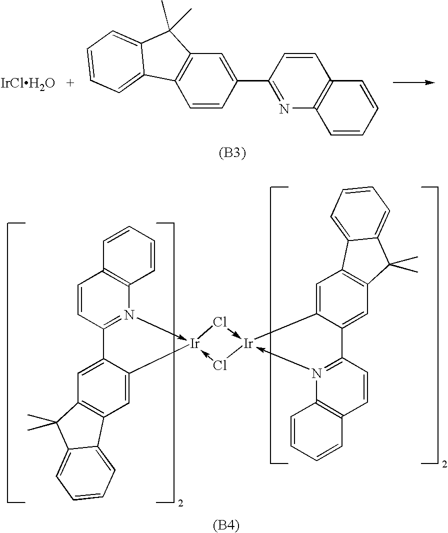

0.71 g (2 mmol) of iridium (III) trihydrate, 2.57 g (8 mole) of (B3), 90 ml of ethoxy ethanol, and 30 ml of water were fed into a 200-ml three-necked flask, and the whole was stirred at room temperature for 30 minutes in a stream of nitrogen and then stirred for 10 hours under reflux. The reactant was cooled to room temperature, and the precipitate was filtered out, washed with water, and washed with ethanol. The resultant was dried under reduced pressure at room temperature to yield 1.56 g of red powder of (B4) (90% yield).

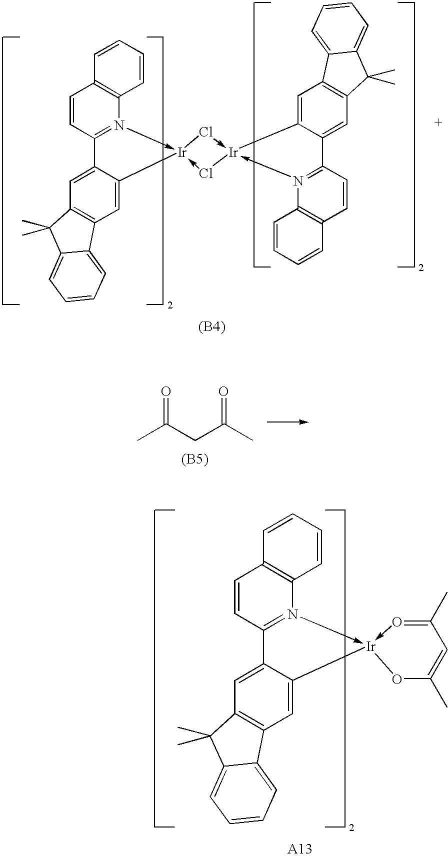

100 ml of ethoxy ethanol, 1.3 g (0.75 mmole) of (B4), 0.2 g (2 mmole) of acetylacetone (B5), and 0.85 g (8 mmole) of sodium carbonate were fed into a 200-ml three-necked flask, and the whole was stirred at room temperature for 1 hour in a stream of nitrogen and then stirred for 7 hours under reflux. The reactant was cooled with ice, and the precipitate was filtered out and washed with water. The precipitate was washed with ethanol and dissolved into chloroform, and then an insoluble matter was filtered. The filtrate was concentrated and recrystallized with chloroform-methanol to yield 1.1 g of red powder of Exemplified Compound No. A13 (77% yield).

932.3 as M⁺ of the compound was observed by

means of MALDI-TOF MS. λmax of the emission spectrum of a solution of the compound in toluene was 615 nm.

### EXAMPLE 2

### Synthesis of Exemplified Compound No. A1

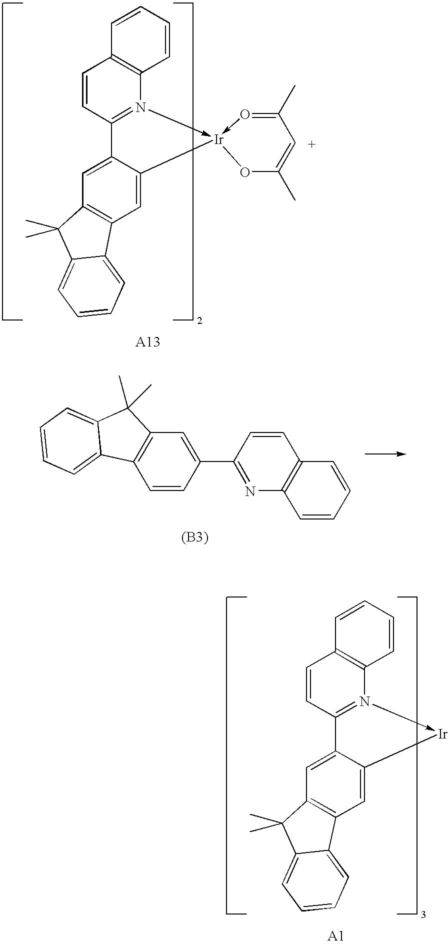

3.21 g (10 mmole) of (B3), 0.93 g (1 mmole) of (A13), and 50 ml of glycerol were fed into a 100-ml three-necked flask, and the whole was stirred under heat at around 180° C. for 8 hours in a stream of nitrogen. The reactant was cooled to room temperature and poured into 170 ml of 1N hydrochloric acid, and the precipitate was filtered out, washed with water, and dried under reduced pressure at 100° C. for 5 hours. The precipitate was purified by means of silica gel column chromatography using chloroform as an eluent to yield 0.15 g of red powder of Exemplified Compound No. A1 (13% yield).

1153.4 as M⁺ of the compound was observed by means of MALDI-TOF MS.

### EXAMPLE 3

### Synthesis of Exemplified Compound No. A50

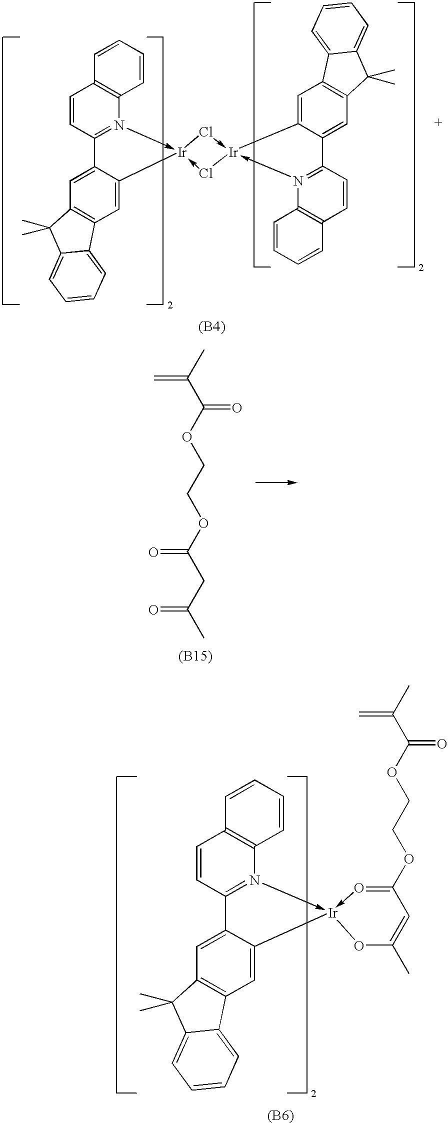

60 ml of ethoxy ethanol, 0.76 g (0.6 mmole) of (B4), 0.38 g (1.8 mmole) of acetoacetoxyethyl methacrylate manufactured by SIGMA-ALDRICH (B15), 0.84 g of sodium carbonate, and 0.0005 g of benzene-1,4-diol (hydroquinone) were fed into a 200-ml three-necked flask, and the whole was stirred at room temperature for 1 hour in a stream of nitrogen and heated to 100° C. over 4 hours. The reactant was cooled with ice and added with 50 ml of water. After that, the precipitate was filtered out and washed with water. The precipitate was washed with 30 ml of ethanol and dissolved into chloroform, and then an insoluble matter was removed. The remainder was recrystallized with chloroform/methanol for purification to yield 0.55 g of red powder of (B6) (54% yield).

813 as M⁺ of the compound was observed by means of MALDI-TOF MS. The photoluminescence of the emission spectrum of a solution of the compound in toluene was measured by means of an F-4500 manufactured by Hitachi, Ltd. to confirm that λmax was 615 nm.

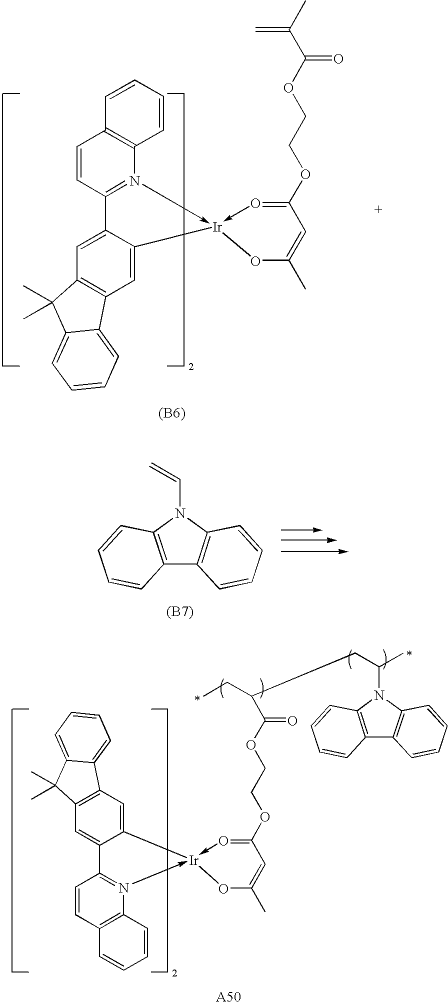

2 ml of N,N′-dimethylformylamide, 104 mg (0.1 mmole) of (B6), 174 mg (0.9 mmole) of vinylcarbazole (VK) (B7), and 1.64 mg (0.001 mmole) of 2,2′-azobis(isobutyronitrile) (AIBN) were fed into a polymerization tube, and the tube was deaerated and sealed. After that, the mixture was stirred under heat at 60° C. for 20 hours. After the completion of the reaction, the mixed solution was reprecipitated with 100 ml of ether three times, and then the resultant powder was dried under heat and reduced pressure to yield 0.2 g of Exemplified Compound A5(Mn=62,000, Mw/Mn=1.3 (in THF, polystylene standard)). According to ¹H-NMR, a molar introduction ratio between (B6) and VK (B7) was about 1:20.

### EXAMPLE 4

### Synthesis of Exemplified Compound No. A51

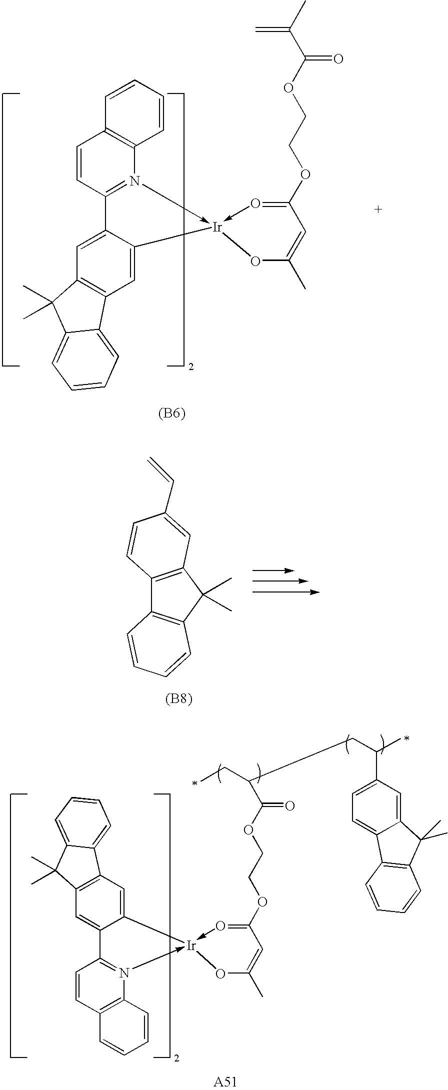

2 ml of chlorobenzene, 104 mg (0.1 mmole) of (B6), 198 mg (0.9 mmole) of (B8), and 1.64 mg (0.001 mmole) of 2,2′-azobis(isobutyronitrile) (AIBN) were fed into a polymerization tube, and the tube was deaerated and sealed. After that, the mixture was stirred under heat at 60° C. for 20 hours. After the completion of the reaction, the mixed solution was reprecipitated with 100 ml of ether three times, and then the resultant powder was dried under heat and reduced pressure to yield 0.2 g of Exemplified Compound A51 (Mn=86,000, Mw/Mn=1.3 (in THF, polystylene standard)) According to 1H-NMR, a molar introduction ratio between (B6) and (B8) was about 1:30.

### EXAMPLE 5

### Synthesis of Exemplified Compound No. A25

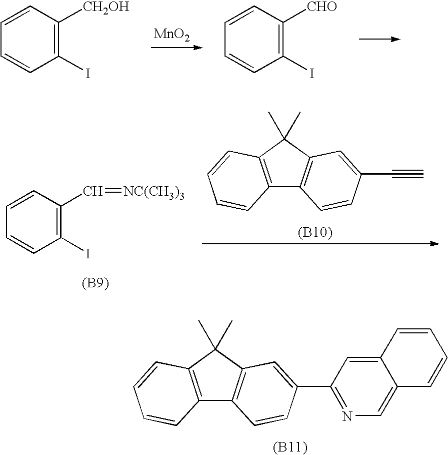

(B11) was synthesized on the basis of Kevin R. et al., Org. Lett., 1999, 1, 553-556. The target product was identified by means of a peak of 321.2 with the aid of DI-MS.

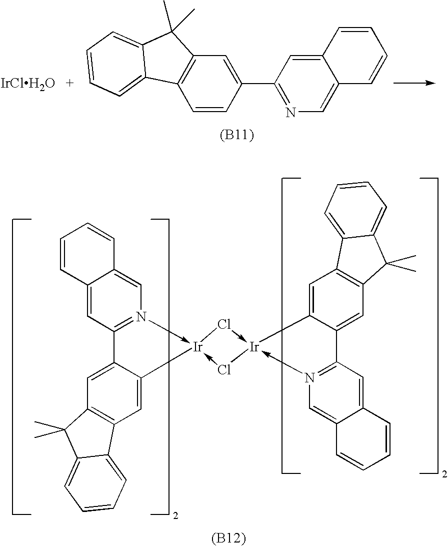

0.71 g (2 mmol) of iridium (III) trihydrate, 2.57 g (8 mole) of (B11), 90 ml of ethoxy ethanol, and 30 ml of water were fed into a 200-ml three-necked flask, and the whole was stirred at room temperature for 30 minutes in a stream of nitrogen and then stirred for 10 hours under reflux. The reactant was cooled to room temperature, and the precipitate was filtered out, washed with water, and washed with ethanol. The resultant was dried under reduced pressure at room temperature to yield 1.25 g of red powder of (B12) (72% yield).

The photoluminescence of the emission spectrum of a solution of (B12) in toluene was measured by means of an F-4500 manufactured by Hitachi, Ltd. to confirm that λmax was 585 nm.

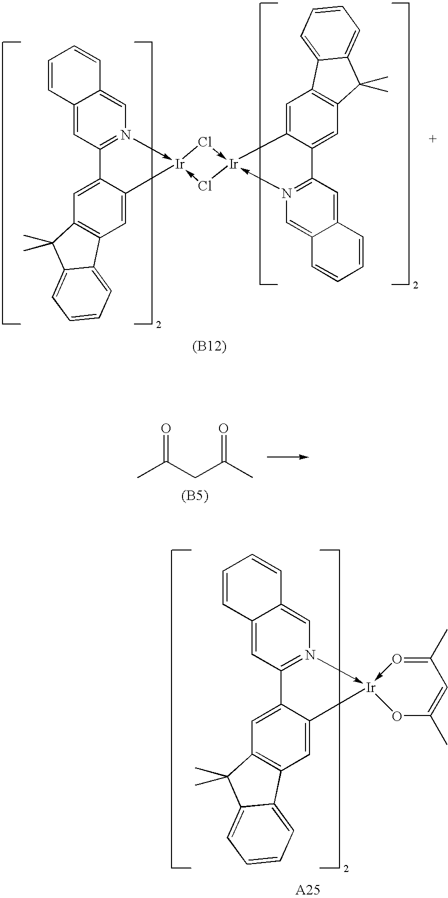

100 ml of ethoxy ethanol, 1.3 g (0.75 mmole) of (B12), 0.2 g (2 mmole) of acetylacetone (B5), and 0.85 g (8 mmole) of sodium carbonate were fed into a 200-ml three-necked flask, and the whole was stirred at room temperature for 1 hour in a stream of nitrogen and then stirred for 7 hours under reflux. The reactant was cooled with ice, and the precipitate was filtered out and washed with water. The precipitate was washed with ethanol and dissolved into chloroform, and then an insoluble matter was filtered. The filtrate was concentrated and recrystallized with chloroform-methanol to yield 1.2 g of red powder of Exemplified Compound No. A25 (85% yield).

932.3 as M⁺ of the compound was observed by means of MALDI-TOF MS. λmax of the emission spectrum of a solution of the compound in toluene was 580 nm.

### EXAMPLE 6

### Synthesis of Exemplified Compound No. A5

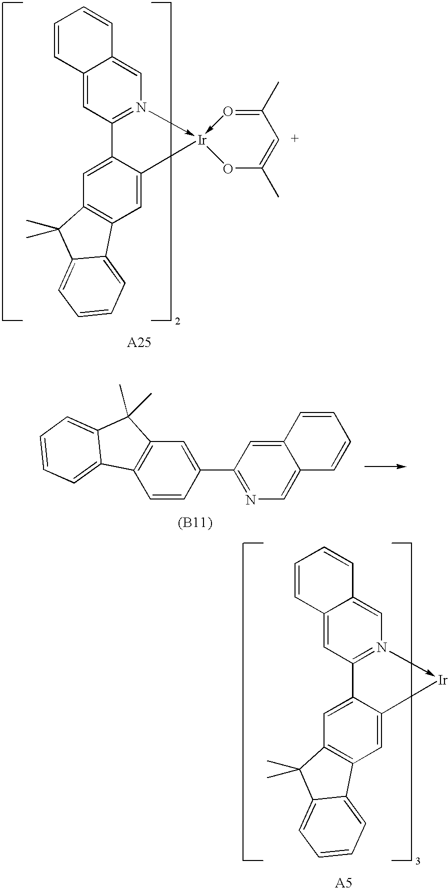

3.21 g (10 mmole) of (B11), 0.93 g (1 mmole) of (A25), and 50 ml of glycerol were fed into a 100-ml three-necked flask, and the whole was stirred under heat at around 180° C. for 8 hours in a stream of nitrogen. The reactant was cooled to room temperature and poured into 170 ml of 1N hydrochloric acid, and the precipitate was filtered out, washed with water, and dried under reduced pressure at 100° C. for 5 hours. The precipitate was purified by means of silica gel column chromatography using chloroform as an eluent to yield 0.40 g of red powder of Exemplified Compound No. A5 (35% yield).

1153.4 as M⁺ of the compound was observed by means of MALDI-TOF MS.

### EXAMPLE 7

### Synthesis of Exemplified Compound No. A32

Exemplified Compound No. A32 was synthesized in the same manner as in Example 5 except that (B12) was used instead of (B10).

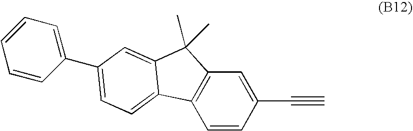

### EXAMPLE 8

### Synthesis of Exemplified Compound No. A4

Exemplified Compound No. A4 was synthesized in the same manner as in Example 6 except that A32 was used instead of A25.

### EXAMPLE 9

### Synthesis of Exemplified Compound No. A16

Exemplified Compound No. A16 was synthesized in the same manner as in Example 1 except that (B13) was used instead of (B5).

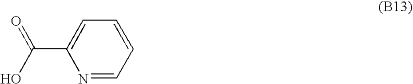

### EXAMPLE 10

### Synthesis of Exemplified Compound No. A21

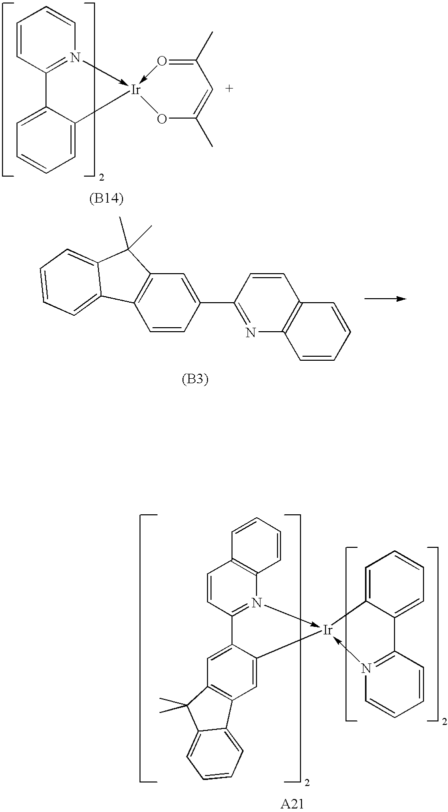

3.21 g (10 mmole) of (B3), 0.6 g (1 mmole) of (B14), and 50 ml of ethylene glycol were fed into a 100-ml three-necked flask, and the whole was stirred under heat at around 170° C. for 8 hours in a stream of nitrogen. The reactant was cooled to room temperature and poured into 170 ml of 1N hydrochloric acid, and the precipitate was filtered out, washed with water, and dried under reduced pressure at 100° C. for 5 hours. The precipitate was purified by means of silica gel column chromatography using ethyl acetate-hexane as an eluent to yield 0.08 g of red powder of Exemplified Compound No. A21 (10% yield).

821.2 as M⁺ of the compound was observed by means of MALDI-TOF MS.

Other exemplified compounds can be synthesized on the basis of Examples 1 to 10 by changing Compounds (B1), (B2), (B5), (B7), (B9), (B10), (B14), and (B15).

### EXAMPLE 11

In this example, a device having 3 organic layers shown in FIG. 5 was used as a device structure.

ITO (the transparent electrode 14) having a thickness of 100 nm was patterned onto a glass substrate (the transparent substrate 15) to have an electrode area of 3.14 mm². The following organic layers and electrode layers were continuously formed onto the ITO substrate through vacuum deposition according to resistance heating in a vacuum chamber at 10⁻⁴ Pa to produce a device.

Hole-transporting layer 13 (40 nm): (Compound A)
Light emission layer 12 (40 nm): (CBP)+(Exemplified Compound A13) 10 wt %
Electron-transporting layer 16 (30 nm): (Bphen)
Metal electrode layer 11-2 (15 nm): KF
Metal electrode layer 11-1 (100 nm): Al

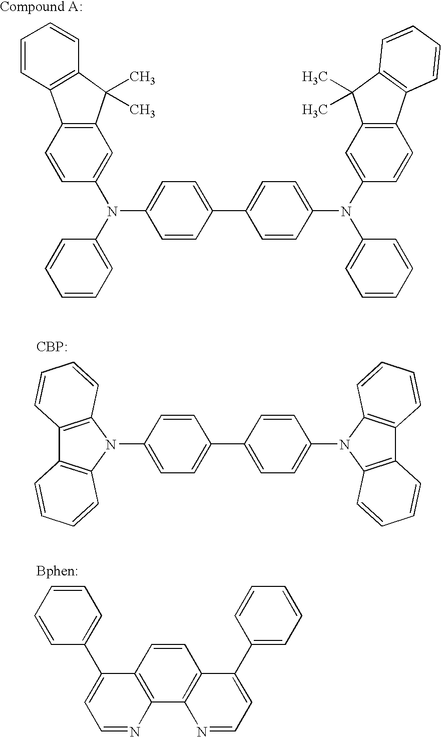

The device had a current efficiency of 9 Cd/A and a power efficiency of 7 lm/W at a luminance of 600 cd/m². At this time, an emission spectrum peaked at 615 nm, and CIE chromaticity coordinates were (0.66, 0.33). Table 1 shows the results.

### EXAMPLES 12 TO 16

In each of the examples, a device was produced in the same manner as in Example 11 except that a compound shown in Table 1 was used instead of Exemplified Compound A13, and the device was similarly evaluated. Table 1 shows the results.

Compound B used in Example 13 is shown below.

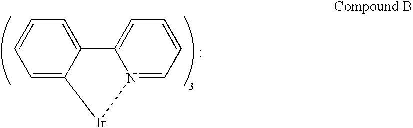

TABLE 1

| | | Current | Power | Emission | |
|---|---|---|---|---|---|
| | Light emission | efficiency | efficiency | spectrum peak | CIE chromaticity |
| | layer dopant | (Cd/A) | (1 m/W) | (nm) | coordinates |
| Example 11 | Exemplified | 9 | 7 | 615 | (0.66, 0.33) |
| | Compound A13 | | | | |
| Example 12 | Exemplified | 10 | 7 | 610 | (0.66, 0.34) |
| | Compound A1 | | | | |
| Example 13 | Compound B | 12 | 9 | 615 | (0.66, 0.34) |
| | (4 wt %) | | | | |
| | Exemplified | | | | |
| | Compound A1 | | | | |
| | (8 wt %) | | | | |
| Example 14 | Exemplified | 14 | 12 | 580 | (0.61, 0.36) |
| | Compound A5 | | | | |
| Example 15 | Exemplified | 10 | 9 | 620 | (0.67, 0.33) |
| | Compound A21 | | | | |
| Example 16 | Exemplified | 9 | 7 | 620 | (0.67, 0.33) |
| | Compound A40 | | | | |

### EXAMPLE 17

In this example, a device having 3 organic layers shown in FIG. 5 was used as a device structure. In the figure, reference numerals 11-1 and 11-2 denote metal electrode layers, and the other reference numerals denote the same layers as those denoted by the reference numerals of FIGS. 1A to 1C.

A PEDOT (for an organic EL) manufactured by Bayer was applied to have a thickness of 40 nm on the ITO substrate used in Example 11 by means of spin coating at 1,000 rpm (20 sec). The resultant was dried in a vacuum chamber at 120° C. for 1 hour to form the hole transport layer 13.

The following solutions were applied to the layer by means of spin coating at 2,000 rpm for 20 seconds in a nitrogen atmosphere to form an organic film having a thickness of 50 nm (the light emission layer 12), and the resultant was dried under the same conditions as those at the time of formation of the PEDOT into a film.

Dehydrated chlorobenzene: 10 g

### Exemplified Compound A51: 100 mg

The substrate was mounted on a vacuum deposition chamber to form Bphen into a film having a thickness of 40 nm through vacuum deposition, thereby forming the electron transport layer 16.

The total thickness of the organic layers was 130 nm.

Next, a cathode having such constitution as described below (the metal electrode 11) was formed.

Metal electrode layer 1 (15 nm): AlLi alloy (Li content 1.8 wt %)
Metal electrode layer 2 (100 nm): Al

A DC voltage was applied in such a manner that the metal electrode 11 and the transparent electrode 14 would serve as a negative electrode and a positive electrode, respectively, to thereby evaluate device characteristics.

The device had a current efficiency of 3 Cd/A and a power efficiency of 2 lm/W at a luminance of 600 cd/m². At this time, an emission spectrum peaked at 615 nm, and CIE chromaticity coordinates were (0.65, 0.33).

### EXAMPLE 18

A device was produced in the same manner as in Example 17 except that Exemplified Compound A50 was used instead of Exemplified Compound A51, and the device was similarly evaluated.

The device had a current efficiency of 3 Cd/A and a power efficiency of 1.2 lm/W at a luminance of 600 cd/m². At this time, an emission spectrum peaked at 615 nm, and CIE chromaticity coordinates were (0.65, 0.33).

This application claims priority from Japanese Patent Application No. 2004-346257 filed on Nov. 30, 2004, which is hereby incorporated by reference herein.

1. A metal complex comprising a partial structure represented by the following general formula (1): 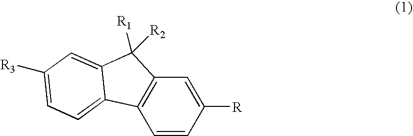
wherein R in the general formula (1) has a partial structure represented by the following general formula (2) or (3): 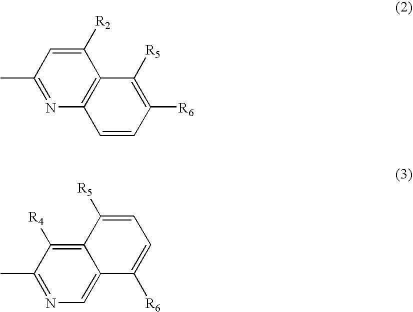
wherein, R₁ to R₆ are each independently selected from a hydrogen atom, a halogen atom, a straight or branched alkyl group having 1 to 20 carbon atoms (one methylene group of the alkyl group, or two or more methylene groups thereof not adjacent to each other may be substituted by —O—, —S—, —CO—, —CO—O—, —O—CO—, —CH═CH—, or —C≡C—, one or two or more methylene groups may be substituted by an arylene group which may have a substituent or a divalent heterocyclic group which may have a substituent, and a hydrogen atom in the alkyl group may be substituted by a fluorine atom), an amino group which may have a substituent, a silyl group which may have a substituent, a phenyl group which may have a substituent, a naphthyl group, a pyrenyl group, a phenanthrenyl group, a crysenyl group, a fluoranthenyl group, a triphenylenyl group, and a heterocyclic group which may have a substituent; in addition, adjacent atoms or groups may bind to each other to form a ring structure.

2. The metal complex according to claim 1, wherein a center metal comprises Ir.

3. The metal complex according to claim 1, which is represented by the following general formula (4):
MLₘL′ₙ (4)
wherein, L and L′ represent bidentate ligands different from each other; m represents 1, 2, or 3 and n represents 0, 1, or 2; provided that m+n=3; a partial structure MLₘ is represented by the following general formula (5) or (6); and a partial structure ML′ₙ is represented by the following general formula (7), (8), or (9); 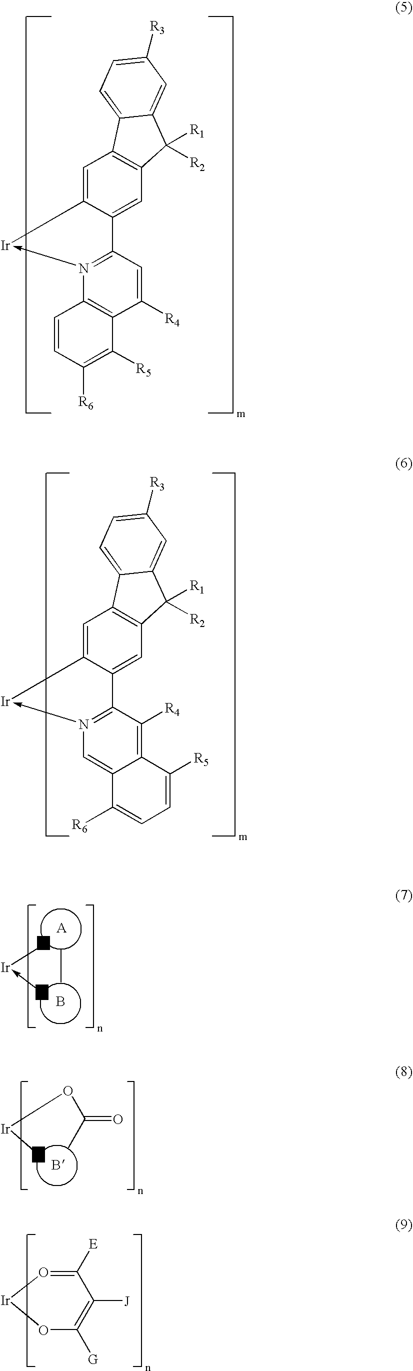
N and C represent a nitrogen atom and a carbon atom, respectively; A represents a cyclic group which may have a substituent bound to a metal atom M via a carbon atom; and B and B′ each represent a cyclic group which may have a substituent bound to the metal atom M via a nitrogen atom;
A and B bind to each other through a covalent bond;
E and G each represent a straight or branched alkyl group having 1 to 20 carbon atoms (a hydrogen atom in the alkyl group may be substituted by a fluorine atom) or an aromatic ring group which may have a substituent {the substituent represents a halogen atom, a cyano group, a nitro group, a trialkylsilyl group (the alkyl groups each independently represent a straight or branched alkyl group having 1 to 8 carbon atoms), or a straight or branched alkyl group having 1 to 20 carbon atoms (one methylene group in the alkyl group, —S—, —CO—, —CO—O—, —O—CO—, —CH═CH—, or —C═C— and a hydrogen atom in the alkyl group may be substituted by a fluorine atom)}; and
J's each represent hydrogen, a halogen, a straight or branched alkyl group having 1 to 20 carbon atoms (a hydrogen atom in the alkyl group may be substituted by a fluorine atom), or an aromatic ring group which may have a substituent {the substituent represents a halogen atom, a cyano group, a nitro group, a trialkylsilyl group (the alkyl groups each independently represent a straight or branched alkyl group having 1 to 8 carbon atoms), or a straight or branched alkyl group having 1 to 20 carbon atoms (one methylene group in the alkyl group, or two or more methylene groups therein not adjacent to each other may be substituted by —O—, —S—, —CO—, —CO—O—, —O—CO—, —CH═CH—, or —C═C— and a hydrogen atom in the alkyl group may be substituted by a fluorine atom)}.

4. A light-emitting device comprising:
a pair of electrodes; and
at least one layer containing an organic compound, the layer being interposed between the electrodes,
wherein the at least one layer containing an organic compound comprises a layer containing the metal complex according to claim 1.

5. The light-emitting device according to claim 4, wherein the layer containing the metal complex comprises a light emission layer, a hole transport layer, or an electron transport layer.

6. The light-emitting device according to claim 4, wherein the light emission layer contains multiple phosphorescent materials.

7. An image display apparatus comprising:
the light-emitting device according to claim 4; and
means for supplying an electrical signal to the light-emitting device.
